(19) United States
(12) Patent Application Publication
(10) Pub. No.: US 2013/0087181 A1
(43) Pub. Date: Apr. 11, 2013

(54) METHOD FOR PRODUCING A PHOTOVOLTAIC MODULE HAVING BACKSIDE-CONTACTED SEMICONDUCTOR CELLS

(71) Applicants: Metin Koyuncu, Kernen (DE); Ulrich Schaaf, Kaisersbach (DE); Andreas Kugler, Alfdorf (DE); Patrick Zerrer, Weinstadt (DE); Martin Zippel, Berlin (DE); Patrick Stihler, Wolfschlugen (DE)

(72) Inventors: Metin Koyuncu, Kernen (DE); Ulrich Schaaf, Kaisersbach (DE); Andreas Kugler, Alfdorf (DE); Patrick Zerrer, Weinstadt (DE); Martin Zippel, Berlin (DE); Patrick Stihler, Wolfschlugen (DE)

(21) Appl. No.: 13/640,145

(22) PCT Filed: Apr. 8, 2011
(86) PCT No.: PCT/EP11/55575

§ 371 Date: Dec. 19, 2012

(30) Foreign Application Priority Data
Apr. 8, 2010 (DE) 10 2010 003 765.6

(51) Int. Cl. H01L 31/18; H01L 31/0224

(52) U.S. Cl. CPC H01L 31/18; H01L 31/022441
USPC 136/244; 438/98

(57) ABSTRACT

A method for producing a photovoltaic module having backside-contacted semiconductor cells which have contact regions provided on a contact side, the method including providing a non-conducting foil-type substrate, placing the contact sides of the semiconductor cells on the substrate, implementing laser drilling which penetrates the substrate to produce openings in the contact regions of the contact sides of the semiconductor cells, depositing a contacting means on the substrate to fill the openings and to form a contacting layer extending on the substrate.

### FIELD OF THE INVENTION

The present invention relates to a method for producing a photovoltaic module having backside-contacted semiconductor cells, and to a photovoltaic module having such backside contacting.

### BACKGROUND INFORMATION

Photovoltaic modules on the basis of conventional semiconductors are made up of a totality of semiconductor cells. Inside these cells, an electrical voltage is produced under the influence of external incident light. The semiconductor cells are expediently interconnected so that the highest possible current intensity can be picked off at the photovoltaic module. This requires contacting of the semiconductor cells and expedient line wiring within the photovoltaic module.

Conventional photovoltaic modules use so-called ribbons for the wiring and cabling. In general, these are conductor segments made of metal, especially copper, which are developed in the form of strips. The contacting between a ribbon and the semiconductor cells to which it is wired usually is implemented as a soft solder connection. The contacts are routed from an upper, light-active side of a semiconductor cell to a rear side, facing away from the light, of an adjacent semiconductor cell. Situated at the contact points between between the ribbon and the semiconductor cell are metallized contact regions in which the soldered connection is implemented.

To increase the light yield of such photovoltaic modules, tests were undertaken to shift the described contacting points entirely to the rear side of the semiconductor cells facing away from the light. This side facing away from the light then forms a contact side of the individual semiconductor cells. The contact regions situated on the common contact side must be contacted using a different potential. Given a multitude of semiconductor cells in an interconnection to be realized, and a particular geometric arrangement, the demands on the precise placement of the contactings are considerable if faulty wiring and short-circuits are to be avoided in reliable manner. The difficulties this entails with regard to the precise positioning of the semiconductor cells in a given cell arrangement in a connection process running simultaneously between the semiconductor cells and different substrates has the result that the backside contacting, which is advantageous with regard to the energy yield of the photovoltaic module, entails a complicated manufacturing process, which, above all, hampers an efficient large-scale production of such modules.

### SUMMARY

In accordance with the present invention, an example method for producing a photovoltaic module having semiconductor cells featuring backside contacting includes the following steps:

In a first method step, a non-conductive, foil-type substrate is provided. In a further step, the contact sides of the semiconductor cells are deposited on the substrate. Then, a point-by-point perforation which penetrates the substrate takes place in order to produce openings in the contact regions of the semiconductor cells. Subsequently, a contacting material is applied on the substrate to fill the openings and to form a contacting layer for the semiconductor cells, the contacting layer extending on the substrate.

In accordance with the present invention, the semiconductor cells are first placed on a substrate. The semiconductor cells are covered by the substrate on their contact sides, and only then, in a subsequent step, the contacts of the semiconductor cells are formed. The contacting of the semiconductor cells is carried out in such a way that the contact points of the semiconductor cells are exposed by drilling. The openings created in the process are then filled with a conductive material. Finally, a contacting layer for the semiconductor cells is applied on the rear substrate side.

An advantage of the example method according to the present invention is that the backside contacting takes place only after the semiconductor cells are already in place on the substrate. The method step of placing the semiconductor cells on the one hand, takes place independently of the actual contacting step of the semiconductor cells on the other. The contacting points are set only after the position of each individual semiconductor cell has been specified. As a result, there is no need to adapt the position of the semiconductor cells to previously specified circuit tracks. Instead, the extension of the circuit track or of each individual contact point is based on the actual position of each individual semiconductor cell. In this way the positional tolerances of each individual semiconductor cell that invariably arise in large scale production processes are completely unproblematic.

After placing the contact sides of the semiconductor cells, the semiconductor cells are expediently able to be laminated.

This permanently joins the semiconductor cells to the substrate (foil and glass), and thereby prevents them from slipping or changing their position in some other manner during the subsequent method steps. In addition, the composite made up of substrate and encapsulated semiconductor cells forms an intermediate product, which is able to be stocked quite readily for subsequent processing steps, if necessary.

In certain cases at least one additional contacting layer may be produced after the contacting means has been applied. The following method steps are executed in the process:

The contacting layer is at least regionally covered by an insulating cover layer. Then, a point-by-point perforation which punctures the cover layer, the substrate and/or the circuit tracks, is carried out in order to produce openings in the contact regions of the semiconductor cells. Subsequently, a contacting means is applied to the cover layer to fill the openings and to form the further contacting layer situated on the cover layer. In this way even more complex interconnections between the semiconductor cells are able to be produced in an uncomplicated manner.

The contacting material may be applied in various ways. The contacting material is able to be applied by printing, spraying or selective soldering.

When the point-by-point perforation is implemented, an image recognition of the semiconductor cells situated on the substrate is able to be carried out in one useful development of the present method, direct referencing of a perforation device on each individual semiconductor cell being provided by the image processing and/or the setting of reference points. This means that the actual location and the position of each individual semiconductor cell are detected in situ, and the exposing of the sections provided for the contacting is also able to take place at precisely the locations that were detected in the image. The positional deviations that occur when setting down the semiconductor cells are therefore able to be compensated without any problems, even if they lie within a considerable tolerance range.

For practical purposes, the image recognition is performed by an X-ray radiography device, and an X-ray image is produced in the process. In the image processing, a contour is detected in the x-ray image. Based on the result of the contour detection, the perforation device is automatically moved to a predefined position in order to produce the individual opening.

For practical purposes, the point-by-point perforation is implemented in the form of laser drilling using a laser drill device as perforation device.

Provided on the side of the device is a photovoltaic module, which has a multitude of semiconductor cells featuring backside contacting, and a substrate, which in accordance with an example embodiment of the present invention may be characterized by the fact that the substrate is developed as foil or as laminate. In the region of the semiconductor cells the substrate has openings, filled so as to be electrically conductive, in order to provide a contacting point between the semiconductor cells; it also has circuit tracks of conductive materials extending on a second substrate side.

The conductive material is usefully developed as conductive laminate, ink, paste or solder.

### BRIEF DESCRIPTION OF THE DRAWINGS

The example method according to the present invention and the photovoltaic module according to the present invention will be described in greater detail in the following text on the basis of exemplary embodiments. It should be noted that the figures are merely descriptive character and is by no means intended to restrict the present invention in any form.

FIG. 1 shows an illustration of the placement step of the semiconductor cells on the substrate.

FIG. 2 shows a lamination step of the semiconductor cells placed on the substrate.

FIG. 3 shows an illustration of the laser drilling of the laminated semiconductor cells.

FIG. 4 shows an illustration of the contacting step of semiconductor cells.

FIG. 5 shows an illustration of a further layer configuration showing an additional laser drilling step.

FIG. 6 shows an illustration of a further contacting step.

FIG. 7 shows a basic representation of an x-ray radiography of the composite made up of substrate and semiconductor cells.

FIG. 8 shows an illustration of a photovoltaic module having a protective layer made of a lacquer layer.

FIG. 9 shows another illustration of a photovoltaic module having a protective layer made of a lacquer system.

### DETAILED DESCRIPTION OF EXAMPLE EMBODIMENTS

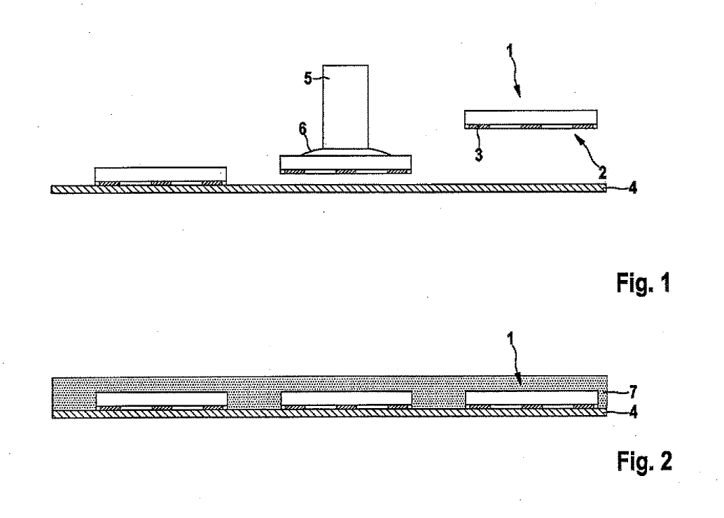

The exemplary method steps explained in the following text are described with the aid of sectional views. FIG. 1 shows a placement step for semiconductor cells on a substrate.

Semiconductor cell 1 is exemplarily developed as a crystalline photovoltaic cell. More specifically, it is made of silicon or a comparable semiconductor material and includes the doped regions (not shown here) for the photovoltaic energy conversion of solar light energy into electrical voltage. Each semiconductor cell has a contact side 2 which features contact regions 3 disposed thereon. The contact regions are usually galvanically metalized or printed.

A substrate 4 is provided for the backside contacting of the semiconductor cells and, in particular, their contact sides 2. This substrate is made of a foil-type, electrically insulating material or a foil-type laminate.

The placement process is performed according to the illustration in FIG. 1, in such a way that the contact sides of the semiconductor cells are resting on the substrate and thus are completely covered by the substrate following the placement step. The placement process as such is carried out by a mechanical placement system 5, the semiconductor cells in the example described here being grasped and released by an aspiration device 6.

The placement of the semiconductor cells may also be replaced by a printing, vapor deposition or lamination process (not shown here) so as to realize an organic photovoltaic module. In such a production process, a polymer acting as organic semiconductor, especially a conjugated polymer having a corresponding electron structure, or a specially synthesized hybrid material is deposited on the foil-type substrate. The composite formed thereby is highly flexible, sufficiently thin and very easy to process further, and the method steps described below are able to be executed without any problems.

In the example at hand, the placement process illustrated in FIG. 1 is followed by an encapsulation step shown in FIG. 2. In the process, the semiconductor cells located on the substrate are covered by a laminate 7. A plastic foil, for example, may be used for the lamination, which is then applied on the semiconductor cells in the course of a vacuum lamination process. Especially ethylene vinyl acetate (EVA) or a plastic material based on organosilicon compounds (silicon) is suitable for the lamination. Both materials are able to be used to thermoplastically form a cover over the entirety of semiconductor cells.

As an alternative to the thermoplastic lamination, the use of reactive lamination materials, known as “dam and fill”, among others, is an option as well. These are in particular substances or mixtures of substances that are castable or spreadable, cure in transparent fashion under the action of electromagnetic radiation, and in doing so, transparently encapsulate the totality of semiconductor cells on the substrate.

The result of the encapsulation step is a composite of the foil substrate, the semiconductor cells and the encapsulation, in which the semiconductor cells are optimally shielded from environmental influences. The composite is easily able to be stored temporarily, stocked as semifinished product and processed further from time to time. This makes for a very flexible production process of the photovoltaic module.

The lamination and encapsulation process illustrated in FIG. 2 is optionally combinable with a lamination on a glass substrate (not shown here) of the later photovoltaic module. In the process, the glass substrate is placed directly on the laminate, and the laminate simultaneously brings about the connection of the composite of semiconductor cells and foil on the glass substrate.

In such a case the photovoltaic module is practically completely prefabricated, while the contacting of the semiconductor cells described in the following text constitutes a final manufacturing step, which, in terms of time and location, is able to be carried out completely separately from the described preparatory steps.

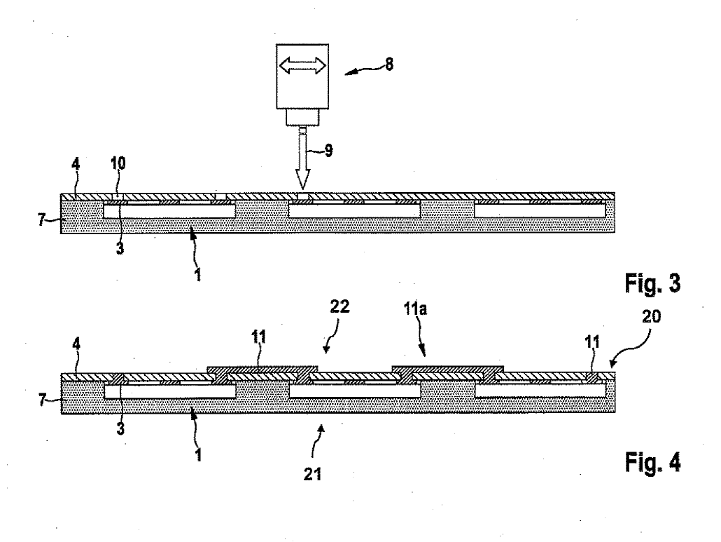

As illustrated in FIG. 3, the composite shown in FIG. 2 is expediently used for the further method steps. The substrate now constitute the upper surface of the layer construction. To begin with, each of the semiconductor cells situated within the composite is scanned in a prior radiography process, which will be described in greater detail below. The positional data of each semiconductor cell, and especially of its contact region, determined in the process are forwarded to a laser drill system 8. This system approaches each semiconductor cell and emits a laser beam 9 in the direction of the composite at the individually required points. In so doing, a series of openings 10 having exposed contact regions 3 is produced on semiconductor cells 1.

The laser drilling step is followed by a contacting step, illustrated in FIG. 4. In this method step, openings 10 are filled with a conductive material 11. Filled openings 10 form selective contacting points of the semiconductor cells.

In conjunction therewith, the conductive material is placed on the surface of the substrate along circuit track structures. This produces the backside contacting of the photovoltaic module. The circuit track structures and the fillings of the conductive material form a backside contacting layer 11a.

Thus, FIG. 4 shows a first exemplary embodiment of a photovoltaitc module 20 according to the present invention. The photovoltaic module has a front side 21 and a backside 22, front side 21 being the side that faces the light, and backside 22 being the side of photovoltaic module 20 that faces away from the light.

Different methods may be used to deposit and apply the contacting layer. For example, it is possible to use a printing method in which an ink or paste having high conductivity, especially a nano-Ag ink or paste, is usable as conductive material.

Vapor deposition or plotting of the conductive material is possible as well. For practical purposes, this is done in such a way that the openings are first filled point by point by depositing conductive drops. The required positional data may be called up directly from a position memory of the laser drill device. Then, the required circuit tracks between the individual contacting points are calculated in a control unit. The circuit tracks to be calculated are translated into control pulses, which in turn are transmitted to a drive mechanism for a plotter pen or a vapor deposition nozzle. The drive mechanism then moves the plotter pen or the vapor deposition nozzle across the substrate surface. The plotter pen or the vapor deposition nozzle actually deposit the circuit tracks.

Filled openings 10 form the selective contacting points of the semiconductor cells that are typical for this specific development of the method.

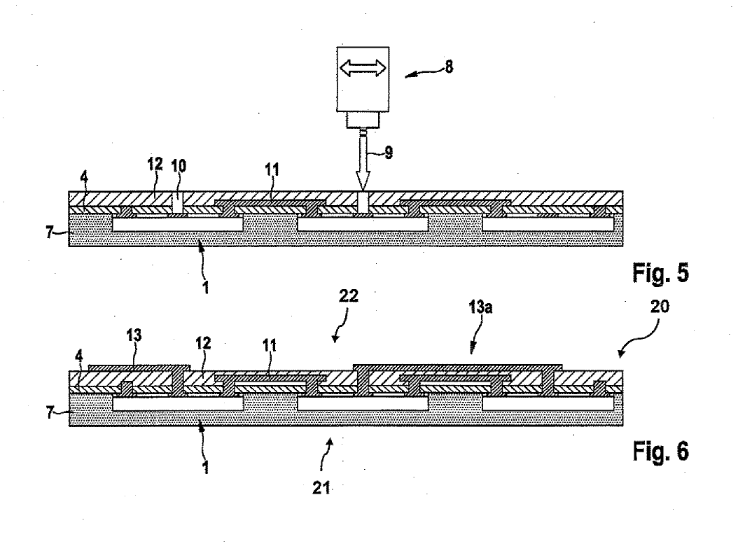

It is basically possible to apply multiple contacting tracks or planes. One pertinent example is shown in FIGS. 5 and 6. To deposit the next contacting plane, the previously produced circuit track structures are at least partially covered by an electrically insulating cover layer 12. For example, the cover layer may be deposited by a lamination process, for which the conventional materials, especially an EVA foil, are able to be utilized. Spraying or printing using a screen-printing method are an option as well.

In the composite produced in this manner additional exposed sections 10 are produced in further contact regions 3 of the semiconductor cells in a repeat application of the previously described method step of laser drilling shown in FIG. 3; subsequently, these sections are again filled with conductive material 13, which results in the formation of a second circuit track layer 13a. The production of the contacting plane following next also allows the introduction of additional electronic components and circuits, should this be required. In the process, in particular a bypass diode circuit is able to be produced.

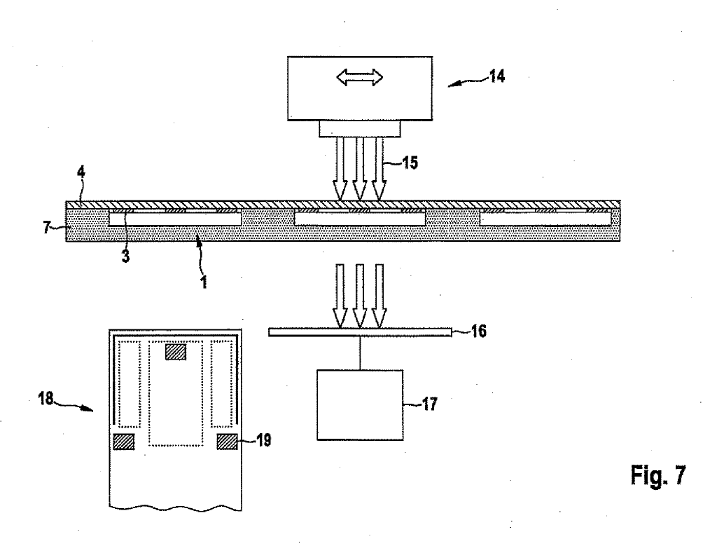

FIG. 7 shows a more detailed illustration of the scanning process mentioned earlier already. In the example at hand, the scanning process is implemented as an x-ray process. The x-ray device provided for this purpose consists of a movable radiation source 14 for generating radiation 15 that penetrates the composite. An X-ray source may be used as radiation source. In such a case radiation 15 is X-ray radiation.

The radiation is collected on an array 16, the array recording an X-ray image of a semiconductor cell 1 situated in the beam path. The raw data determined in this manner are transmitted to an image processing unit 17, especially a computer on which an image processing program has been installed.

The image processing device performs a structure detection on the X-ray image, during which the positions of the forms contained in the image are determined, stored and forwarded to a control unit of the laser drill device.

Additionally, a schematic x-ray image 18 of a segment of a semiconductor cell is illustrated. Due to the increased absorption capacity of the metalized contact regions, the contact regions manifest themselves as clearly detectable contours 16 whose position is able to be determined unequivocally.

The image recognition of the contact regions may also be replaced or supplemented by detecting a fiducial. In this case, semiconductor cells containing definite reference structures that are clearly visible in the X-ray image are set down on the substrate, the position of each contact region to be exposed in relation to the reference structures being known in advance, which thus allows them to be calculated from the position of the fiducial. In particular cross structures which define a local coordinate system for each individual semiconductor cell may be used as fiducial. This coordinate system is recorded by the image-generating method. The position of each individual contact region within the coordinate system is known in advance for each semiconductor cell. This makes it possible to determine the contact regions from the position of the fiducial, even in those cases where these regions do not show any contour in the X-ray image.

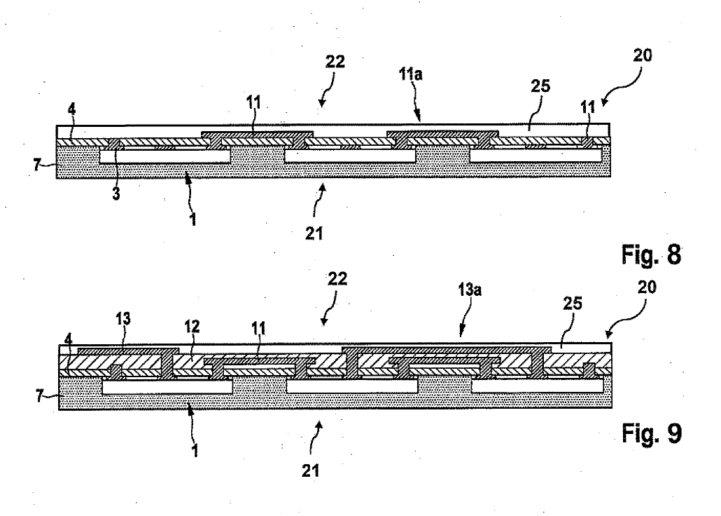

In an advantageous manner, photovoltaic module 20 produced according to the present invention also provides the option of depositing a protective layer 25, consisting of a lacquer system, on rearside contacting layer 11a, 13a. Toward this end, protective layer 25 made of a lacquer system may be deposited both on rearside 22 of a photovoltaic module 20 having precisely one contacting layer 11a (FIG. 8) and on rearside 22 of a photovoltaic module 20 having a plurality of contacting layers 11a, 13a (FIG. 9).

Until now, such weather-resistant protective layers have frequently been made of polyvinyl fluoride (Tedlar) plastic composite foils or of glass. These materials are expensive in comparison with lacquer, and their processing is less flexible. Depending on the requirements, protective layer 25 may very advantageously be locally deposited, either only at specific locations or else across the entire surface on a rearside 22 of photovoltaic module 20.

The application of protective layer 25 in the form of a lacquer system may be accomplished by rolling, spraying or laminating foils or powder layers. In one specific development, the lacquer system includes precisely one layer. As an alternative, the lacquer system may consist of multiple layers. It should be noted that a protective layer 25 made up of multiple layers is advantageously able to compensate for the non-planar topography of backside 22 of photovoltaic module 20 caused by production-related reasons.

After protective layer 25 has been deposited, a separate process step for an optimal curing and drying of the layer may also be carried out, if appropriate.

In addition, the example method provides the opportunity to generate structures in protective layer 25 so as to form design elements. Design elements in particular could be colors, color effects, lettering, numbers or also symbols of all types. Conventional technologies are used for integrating the design elements into protective layer 25.

Additional developments and modifications are possible.

1-15. (canceled)

16. A method for producing a photovoltaic module having backside-contacted semiconductor cells which include contact regions provided on a contact side, the method comprising:
providing a non-conducting foil-type substrate;
placing contact sides of the semiconductor cells on the substrate;
performing a point-by-point perforation which penetrates the substrate to produce openings in contact regions of the contact sides of the semiconductor cells; and
depositing a contacting material on the substrate to fill the openings and to form a contacting layer extending on the substrate.

17. The method as recited in claim 16, wherein after the contact sides of the semiconductor cells have been placed on the substrate, the semiconductor cells are laminated onto the substrate to cover the semiconductor cells by a laminate made of one of a ethylene vinyl acetate or plastic on the basis of organosilicon compounds.

18. The method as recited in claim 16, wherein at least one additional contacting layer is produced after the contacting material has been applied, the at least one additional contacting layer being produced by:
at least sectionally covering the contacting layer by an insulating cover layer;
performing a point-by-point perforation which punctures at least one of the cover layer, the substrate, and circuit tracks in order to produce openings in the contact regions of the semiconductor cells; and
depositing a contacting material on the cover layer to fill the openings and to form the further contacting layer extending on the cover layer.

19. The method as recited in claim 16, wherein the application of the contacting material is implemented by one of printing, spraying or selective soldering.

20. The method as recited in claim 16, wherein image recognition of the semiconductor cells situated on the substrate is performed during the point-by-point perforation, and direct referencing of a perforation device on each individual semiconductor cell is implemented via at least one of image processing and reference-point setting.

21. The method as recited in claim 18, wherein an x-ray image is produced by an x-ray radiography device for image-recognition purposes, a contour detection being implemented in each radiography image during the image processing, and, based on a result of the contour detection, a perforation device automatically is moved to a position determined therefrom in order to produce the individual openings.

22. The method as recited in claim 16, wherein the point-by-point perforation is implemented as laser drilling, using a laser drill device.

23. The method as recited in claim 16, wherein a protective layer made of a lacquer system is deposited on a rearside contacting layer.

24. The method as recited in claim 23, wherein the protective layer is deposited on a rear side of the photovoltaic module across a full surface.

25. The method as recited in claim 23, wherein the deposition of the protective layer is performed one of by rolling, spraying, laminating foils, or powder coating.

26. The method as recited in claim 23, wherein the lacquer system includes precisely one layer.

27. The method as recited in claim 23, wherein the lacquer system includes a plurality of layers.

28. The method as recited in claim 23, wherein structures are developed in the protective layer so as to form design elements.

29. A photovoltaic module, comprising:
a multitude of semiconductor cells having rearside contacting and a substrate, the substrate being an insulating foil and the semiconductor cells resting on a first substrate side via their contact sides, the substrate having openings filled so as to be electrically conductive for the contacting between the semiconductor cells on the first substrate side, and at least one contacting layer extending on a second substrate side.

30. The photovoltaic module as recited in claim 29, wherein the conductive material is at least one of a conductive laminate, a track applied in the form of ink, a paste, and solder.
